(19) United States
(12) Patent Application Publication
(10) Pub. No.: US 2008/0217685 A1
(43) Pub. Date: Sep. 11, 2008

(54) SEMICONDUCTOR DEVICE AND METHOD FOR MANUFACTURING THE SAME

(76) Inventor: Jong-Min Kim, Seoul (KR)

Correspondence Address: SHERR & NOURSE, PLLC, 620 HERNDON PARKWAY, SUITE 200, HERNDON, VA, 20170, US

(21) Appl. No.: 11/849,793

(22) Filed: Sep. 4, 2007

(30) Foreign Application Priority Data
Sep. 13, 2006 (KR) 10-2006-0088417

(51) Int. Cl. H01L 29/78; H01L 21/336

(52) U.S. Cl. 257/344; 438/296; 257/E29.266; 257/E21.437

(57) ABSTRACT

A semiconductor device includes an isolation layer for dividing a silicon substrate into an active region and an inactive region, a gate electrode formed over the silicon substrate, a gate oxide layer formed around a sidewall of the gate electrode to expose an upper portion of the sidewall of the gate electrode, a gate insulation layer formed between the silicon substrate and the gate electrode, an epitaxial layer formed over the gate electrode and the active region around the gate electrode; a lightly doped drain region formed in a surface of the silicon substrate around the gate electrode, a gate spacer formed around the sidewall of the gate electrode including the gate oxide layer; source and drain regions formed in the surface of the silicon substrate at sides of the gate spacer, and a protective layer formed over the entire surface of the silicon substrate.

The present application claims priority under 35 U.S.C. 119 to Korean Patent Application No. 10-2006-0088417 (filed on Sep. 13, 2006), which is hereby incorporated by reference in its entirety.

### BACKGROUND

A field effect transistor (FET) is a transistor having a plurality of carriers which move from a source electrode to a drain electrode by way of a gate electrode. One type of FET is a metal oxide semiconductor field effect transistor (MOSFET). MOSFETs show superior electrical characteristics, and may be configured to include an oxide layer formed on and/or over a silicon substrate and a silicon electrode formed on and/or over the oxide layer. This configuration permits adjustment of electric charge flow in a silicon surface by an electric field.

As the minimum size, weight and thickness requirements decreases in semiconductor devices, the size of FETs becomes smaller. The decrease in size of FETs reduces the effective length of a gate channel, which results in short channel effects. Short channel effects in turn, reduces punch through characteristics between the source electrode and the drain electrode.

To overcome short channel effects, some transistor fabrication processes provide a source/drain structure having a lightly doped drain (LDD) structure. The LDD is formed in source and drain regions to achieve a shallow junction which restricts short channel effects. The LLD structure has its drawbacks. For instance, LDD structures are not applicable for semiconductor devices having a gate width of less than 0.35 μm, and has a limit to form the shallow junction.

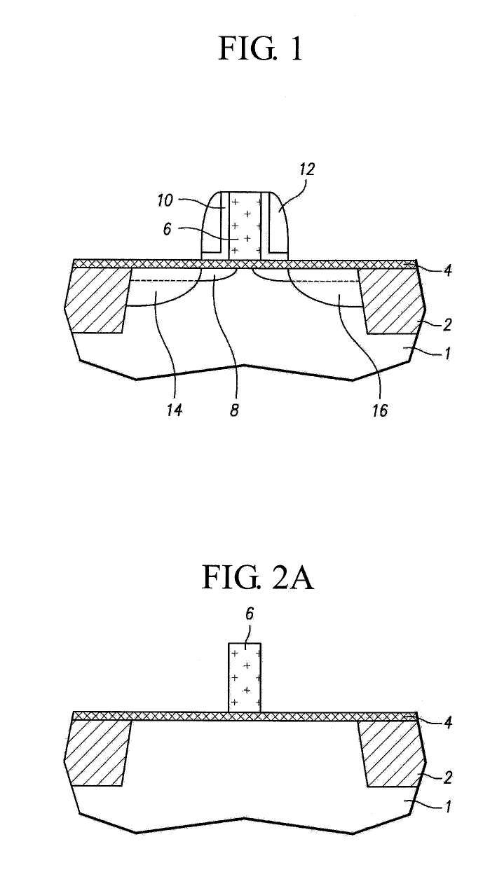

As illustrated in example FIG. 1, a conventional semiconductor device includes isolation layer 2 for dividing silicon substrate 1 into an active region and an inactive region, gate insulation layer 4 formed on and/or over silicon substrate 1 and gate electrode 6 also formed over substrate 1. Gate oxide layer 10 is formed around a sidewall of gate electrode 6 and impurities are implanted to form LDD region. Gate spacers 12 are formed adjacent sidewalls of gate oxide layer 10, and source region 14 and drain region 16 are formed in LDD region 8.

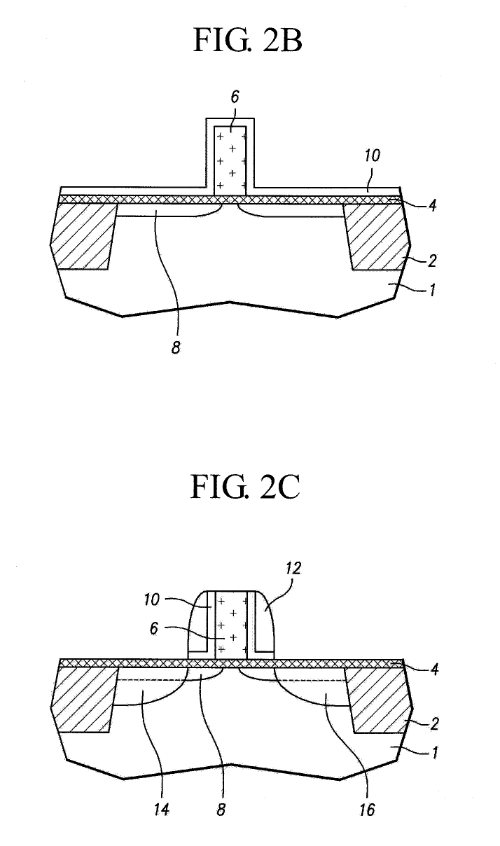

As illustrated in example FIG. 2A, fabrication of a semiconductor device may include sequential forming of isolation layer 2, gate insulation layer 4, and gate electrode 6 on and/or over silicon substrate 1. Isolation layer 2 is formed using a shallow trench isolation (STI) process and defines an inactive region and an active region where formation of a transistor will occur.

The formation of gate insulation layer 4 and a gate metal layer are sequentially formed over the silicon substrate 1 using a deposition process. Gate insulation layer 4 may be composed of an insulation material, such as SiO₂, SiON, or the like. The gate metal layer may be composed of poly-silicon, silicon germanium (SiGe), or the like. Gate electrode 6 is formed using a mask to pattern the gate metal layer by way of a photolithographic process.

As illustrated in example FIG. 2B, gate oxide layer 10 is formed on and/or over gate insulation layer 4 while LDD region 8 is formed underneath gate insulation layer 4. Particularly, gate oxide layer 10 is formed on and/or over gate insulation layer 4 using a deposition process. Gate oxide layer 10 may be formed on a surface of gate electrode 6 by oxidizing the surface of gate electrode 6 to a thickness of between approximately 12 to 20 Å.

As illustrated in example FIG. 2C, gate oxide layer 10 is patterned using a dry etching process. During the dry etching process, a portion of gate oxide layer 10 formed on and/or over the gate electrode 6 is removed to expose an upper surface of gate electrode 6.

LDD regions 8 are formed on both sides of gate electrode 6, using gate oxide layer 10 as a mask. Ions are injected into exposed silicon substrate 1 to form LDD region 8 such that LDD region 8 partially overlaps gate electrode 6. Source region 14 and drain region 16 are formed in LDD region 8.

Gate spacer 12 is formed around the sidewall of gate oxide layer 10 by depositing an insulation layer such as silicon nitride (SiN) on and/or over gate oxide layer 10 using a chemical vapor deposition (CVD) process. The silicon nitride layer is then patterned using a photolithography process to form gate spacer 12.

A semiconductor device is complete once ions are injected into exposed LDD region 8 of silicon substrate 1 to form source region 14 and drain region 16.

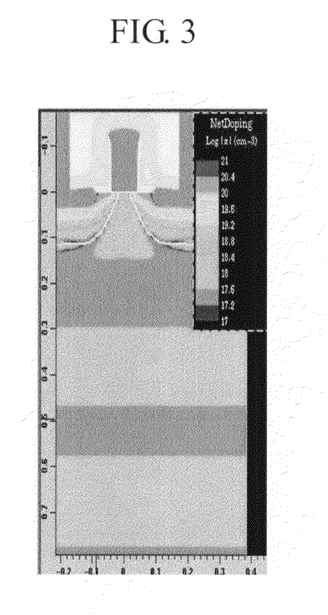

The fabrication of a semiconductor device in such a manner is not without defects. For instance, a low ion injection energy of 2 keV or less is required upon the formation of the LDD region and source and drain regions. Consequently, instability may result during the ion injection process. After the ion injection process, a short duration heat treatment such as a spike heat treatment must be performed, which may deteriorate the activation efficiency of impurities. The overlap area of the LDD region and the gate channel is increased as a result of the injection of LDD ions being performed directly into the gate channel and diffused to the underside of the gate channel by a heat-treatment process. As illustrated in example FIG. 3, the effective length of the gate channel is reduced, resulting in aggravated short channel effects. Moreover, the increased overlap area of the LDD region and the gate channel results in serious hot carrier effect and a higher overlap capacitance between the gate electrode and the source and drain regions. Such a higher overlap capacitance serves to increase the delay time of a ring oscillator.

### SUMMARY

Embodiments relate to a method of forming a semiconductor device capable of controlling short channel effects. Embodiments relate to a semiconductor device that includes a device isolation layer on and/or over a silicon substrate for dividing the silicon substrate into an active region and an inactive region, a gate electrode on and/or over the silicon substrate. A gate oxide layer may be formed adjacent a sidewall of the gate electrode to expose a partial upper portion of the sidewall of the gate electrode. A gate insulation layer interposed between the silicon substrate and the gate electrode, an epitaxial layer on and/or over the gate electrode and the active region. The epitaxial layer can have a mushroom-type shape and be given a width larger than the width of the gate electrode and the gate insulation layer in a channel region. A lightly doped drain (LDD) region formed in the silicon substrate around the gate electrode. A gate spacer formed around the sidewall of the gate electrode. Source and drain regions formed in the surface of the silicon substrate at sides of the gate spacer. A protective layer on and/or over the silicon substrate.

In accordance with embodiments, a gate oxide layer may be etched on and/or over the silicon substrate to a thickness smaller than that of the epitaxial layer. After etching the gate oxide layer, a bird's beak may be formed between the gate insulation layer, the gate oxide layer, and the epitaxial layer on the source and drain regions.

Embodiments relate to a method for manufacturing a semiconductor device including at least one of the following steps: forming a device isolation layer on and/or over a silicon substrate to divide the silicon substrate into an active region and an inactive region; forming a gate insulation layer on and/or over a silicon substrate; forming a gate electrode on and/or over the gate insulation layer; forming a gate oxide layer on and/or over the silicon substrate to expose an upper surface and a partial sidewall of the gate electrode; forming an epitaxial layer on and/or over the gate electrode and the active region around the gate electrode to width larger than that of the gate insulation layer; forming a LDD region in a surface of the silicon substrate around the gate electrode; forming a gate spacer around a sidewall of the gate electrode; forming source and drain regions by injecting ions into the surface of the silicon substrate at sides of the gate spacer; and forming a protective layer on and/or over the silicon substrate. After formation of the epitaxial layer, a gate oxide layer may be patterned around the sidewalls of the gate electrode using an isotropic wet etching process method. The gate oxide layer may be etched to a thickness lower than that of the epitaxial layer by performing a poly-oxidation process before forming the protective layer.

The gate oxide layer and the gate insulation layer may be patterned simultaneously by an anisotropic over-etching process. The epitaxial layer may be formed by a homo epitaxy process. The gate oxide layer may have a thickness of between approximately 20 Å to 150 Å.

### DRAWINGS

Example FIG. 1 illustrates a semiconductor device.

Example FIGS. 2A to 2C illustrate a method for manufacturing a semiconductor device.

Example FIG. 3 illustrates a semiconductor device.

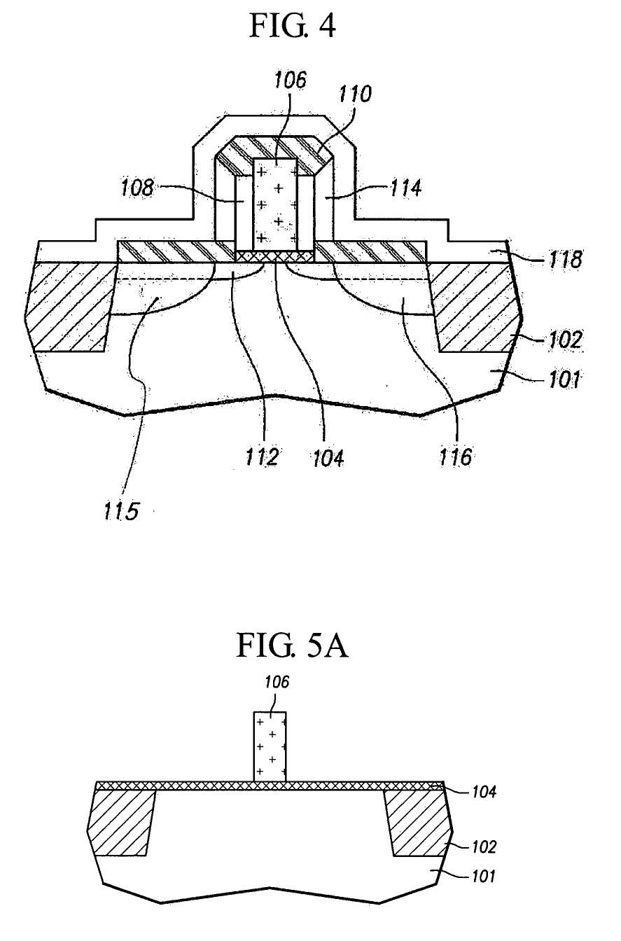

Example FIG. 4 illustrates a semiconductor device, in accordance with embodiments.

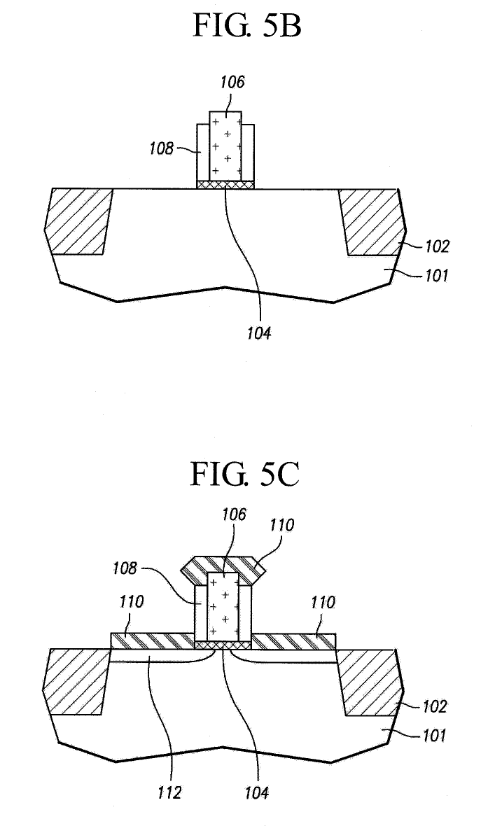

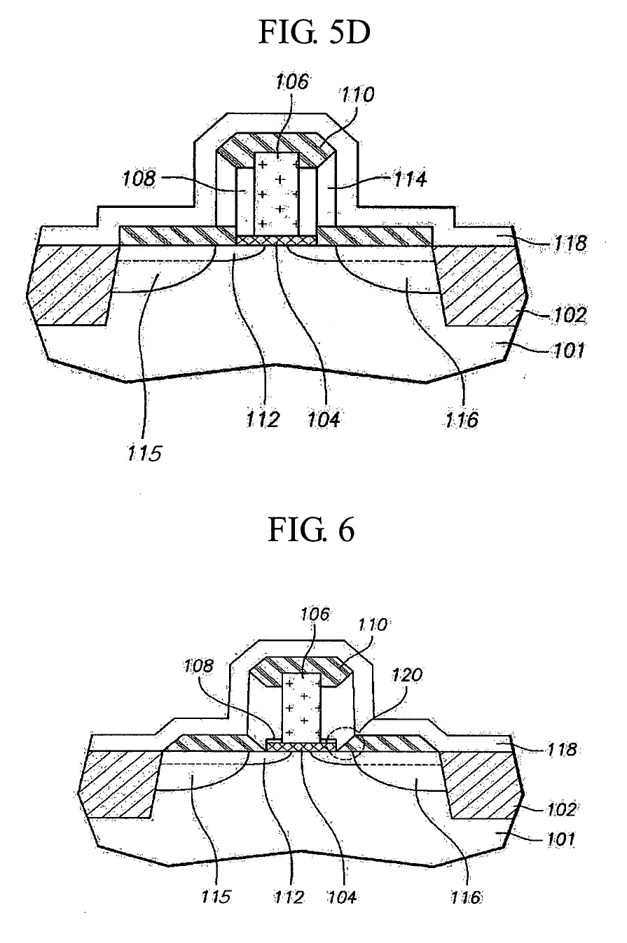

Example FIGS. 5A to 5D illustrate a method for manufacturing a semiconductor, in accordance with embodiments.

Example FIG. 6 illustrates a semiconductor device, in accordance with embodiments.

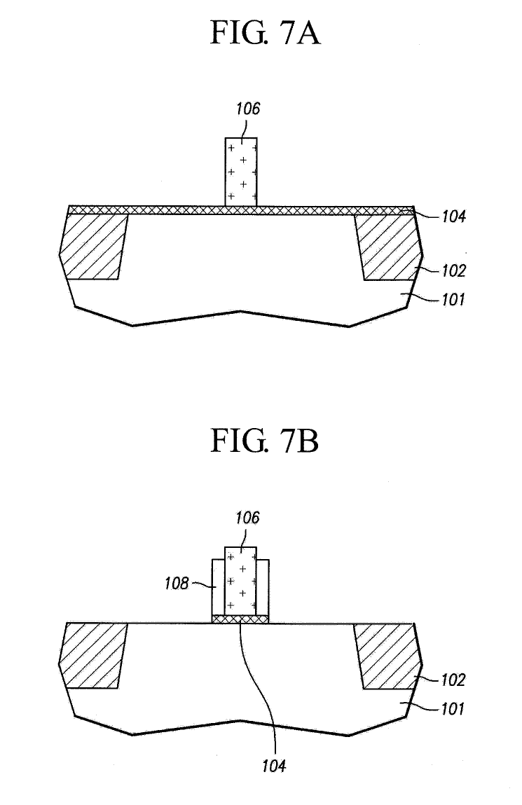

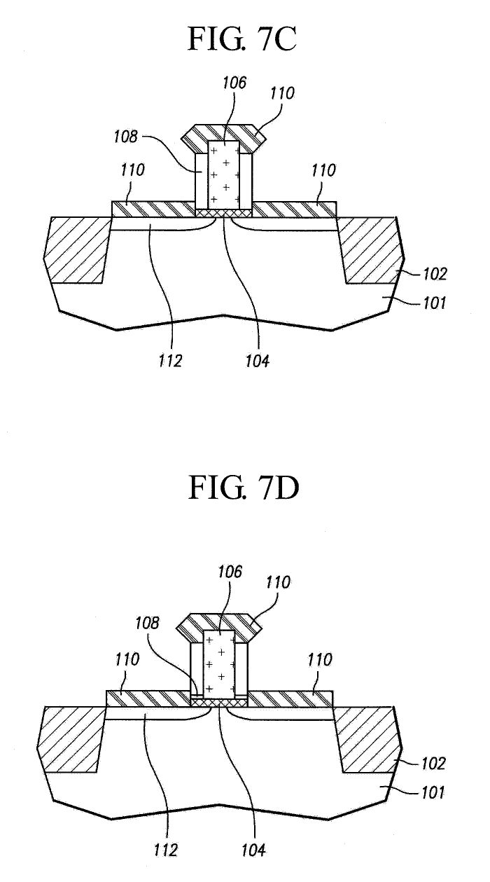

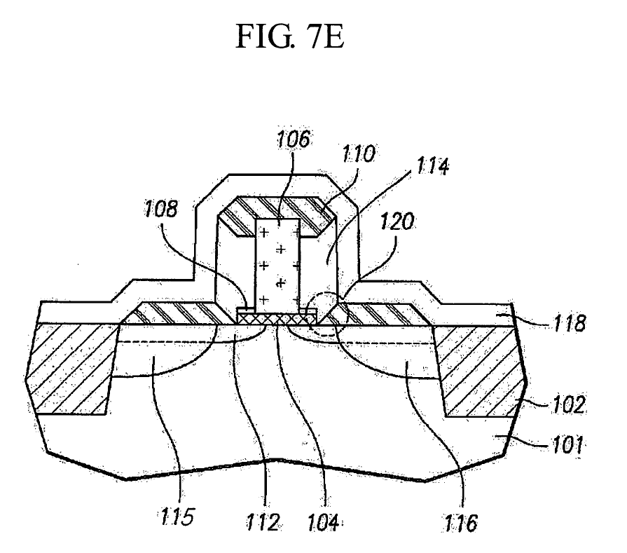

Example FIGS. 7A to 7E illustrate a method for manufacturing a semiconductor, in accordance with embodiments.

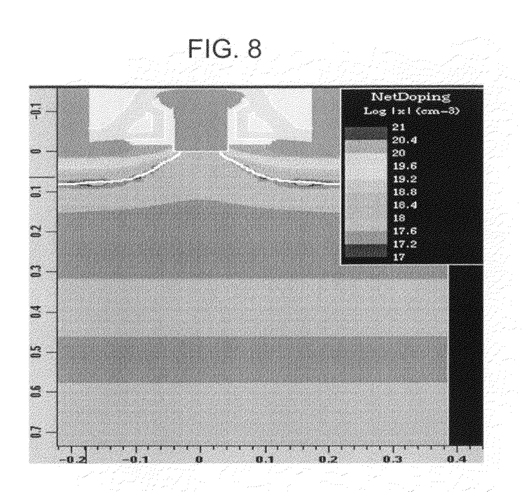

Example FIG. 8 illustrates a semiconductor device, in accordance with embodiments.

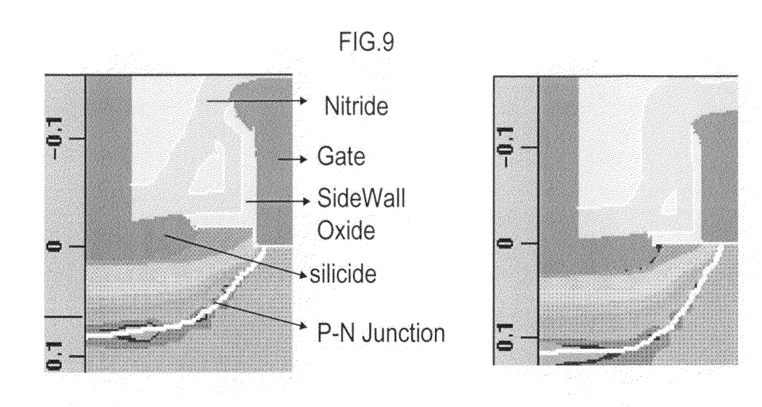

Example FIG. 9 illustrates a simulation of a comparative analysis of separate semiconductor devices.

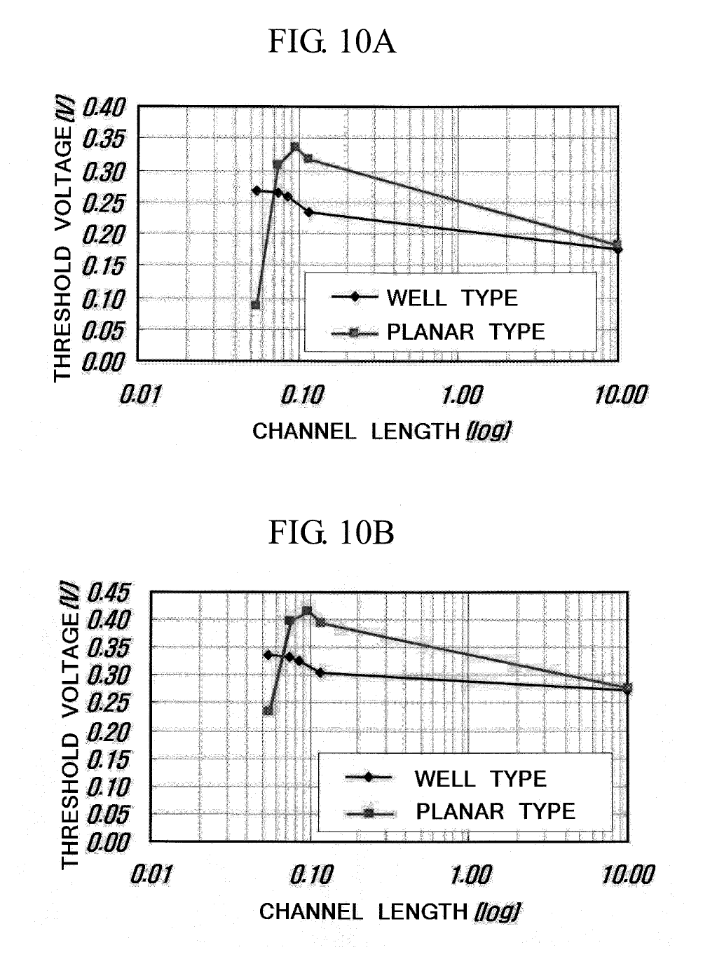

Example FIGS. 10A and 10B illustrate graphs of a comparative analysis of separate semiconductor devices in relation to threshold voltage and channel length.

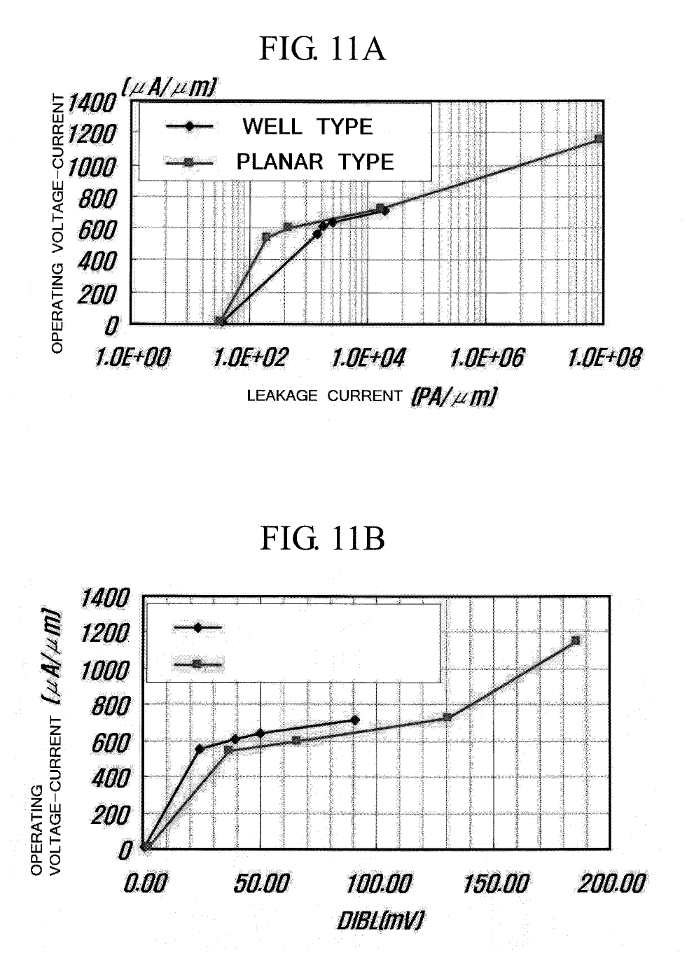

Example FIGS. 11A and 11B illustrate graphs of a comparative analysis of separate semiconductor devices in relation to operating voltage-current and leakage current.

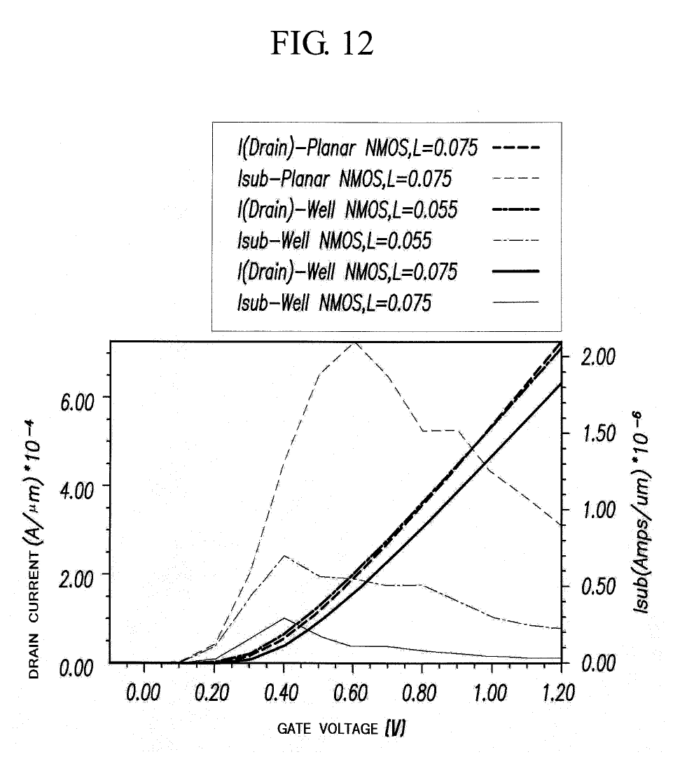

Example FIG. 12 illustrates a graph of a comparative analysis of separate semiconductor devices in relation to hot carrier characteristics.

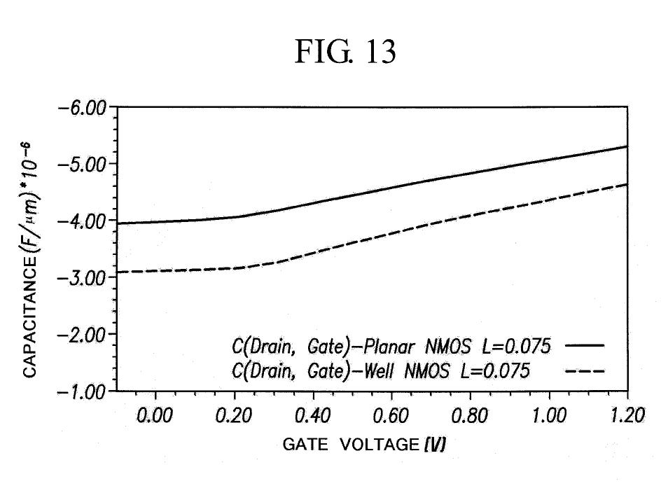

Example FIG. 13 illustrates a graph of a comparative analysis of separate semiconductor devices in relation to overlap capacitance.

### DESCRIPTION

As illustrated in example FIG. 4, in accordance with embodiments is a semiconductor device including device isolation layer 102 may be formed on and/or over a silicon substrate. Device isolation layer 102 can divide silicon substrate 101 into an active region and an inactive region. Gate electrode 106 may be formed on and/or over silicon substrate 101. Gate oxide layer 108 formed around sidewalls gate electrode 106 to a height exposing an upper portion of gate electrode 106. Gate insulation layer 104 may be interposed between silicon substrate 101 and gate electrode 106. Epitaxial layer 110 may be formed on and/or over the gate electrode 106, and particularly, may be formed on and/or over the active region of gate electrode 106 to a width larger than that of gate electrode 106 and gate insulation layer 104. Epitaxial layer 110 may be formed having a mushroom-like shape.

LDD region 112 may be formed in a surface of silicon substrate 101 around gate electrode 106. Gate spacer 114 may be formed around the sidewall of the gate electrode 106 and gate oxide layer 108. Source region 115 and drain region 116 may be formed in the surface of silicon substrate 101 adjacent respective side portions of gate spacer 114. Finally, protective layer 118 may be formed on and/or over the entire surface of silicon substrate 101.

As illustrated in example FIGS. 5A to 5D, a method for manufacturing a semiconductor device in accordance with embodiments include sequentially forming device isolation layer 102, gate insulation layer 104, and gate electrode 106 on and/or over silicon substrate 101. Device isolation layer 102 may be formed on and/or over silicon substrate 101 using a shallow trench isolation (STI) process. Device isolation layer 102 defines the active region where an actual transistor device will be formed.

Next, gate insulation layer 104 and a gate metal layer are sequentially formed on and/or over silicon substrate 101 using a deposition process. Gate insulation layer 104 may be composed of an insulation material such as SiO₂, SiON, or the like. The gate metal layer may be composed of poly-silicon, silicon germanium (SiGe), or the like. The gate metal layer may be used as a mask and patterned using a photolithography process to form gate electrode 106.

As illustrated in example FIG. 5B, gate oxide layer 108 may be formed around the sidewall of gate electrode 106. Gate oxide layer 108 can be formed on and/or over the entire surface of silicon substrate 101 and gate insulation layer 104 using a deposition method. Gate oxide layer 108 may be formed on a surface of gate electrode 106 by oxidizing the surface of gate electrode 106. Gate oxide layer 108 may have a thickness of in a range between approximately 20 to 150 Å in order to reduce an overlap capacitance between gate electrode 106 and source region 115 and drain region 116 at sides of gate electrode 106. The stated thickness range for gate oxide layer 108 is provided to achieve a desired LDD resistance.

Gate insulation layer 104 and gate oxide layer 108 can be patterned using an anisotropic over-etching process in which a portion of gate insulation layer 104 is left directly beneath gate electrode 106 and gate oxide layer 108 and the remaining portion removed. An upper surface and a partial sidewall of gate electrode 106 may be exposed using an anisotropic over-etching process.

As illustrated in example FIG. 5C, epitaxial layer 110 may be formed on and/or over gate electrode 106 and source region 115 and drain region 116. LDD region 112 may be formed in silicon substrate 101 beneath epitaxial layer 110. Epitaxial layer 110 may be formed on and/or over the gate electrode 106 and source region 115 and drain region 116 using a homo-epitaxy process. Epitaxial layer 110 may be formed around the exposed partial sidewall of gate electrode 106 and the upper surface of gate electrode 106. In order to create a low resistance, epitaxial layer 110 may be configured having a mushroom-type shape with a width larger than a channel length.

Subsequently, using gate electrode 106 including gate oxide layer 108 as a mask, ions are injected into silicon substrate 101 to form LDD region 112 such that LDD region 112 partially overlaps gate electrode 106.

As illustrated in example FIG. 5D, gate spacers 114 may be formed around the sidewalls of gate electrode 106 and gate oxide layer 108. Source region 115 and drain region 116 may be formed in silicon substrate 101 at positions not corresponding with the spatial position of gate electrode 106. Protective layer 118 may be formed on and/or over the entire surface of silicon substrate 101.

After formation of gate insulation layer 104, a silicon nitride (SiN) layer may be deposited on and/or over silicon substrate 101 and LDD region 112 using a chemical vapor deposition (CVD) process. The silicon nitride layer may be patterned using a photolithography process to form gate spacer 114 around the sidewalls of gate electrode 106 and gate oxide layer 108.

In order to form source region 115 and drain region 116, ions are injected into exposed LDD region 112 of silicon substrate 101. Source region 115 and drain region 116 may be formed having an underside junction. Thereafter, a heat-treatment process may be performed to activate the injected ions.

Finally, an insulation layer such as silicon nitride (SiN) layer, may be deposited using a low pressure chemical vapor deposition (LPCVD) process, to form protective layer 118 on and/or over silicon substrate 101. Protective layer 118 may serve as a capping layer for protecting a transistor and an etching-barrier layer.

As illustrated in example FIG. 6, in accordance with embodiments is a semiconductor device having gate oxide layer 108 that may be etched to a height lower than a portion of epitaxial layer 110 formed on and/or over source region 115 and drain region 116. Bird's beak 120 may be formed between gate insulation layer 104, gate oxide layer 108 and the portion of epitaxial layer 110 formed on and/or over source region 115 and drain region 116.

As illustrated in example FIGS. 7A to 7E, in accordance with embodiments, a method for manufacturing the semiconductor device may include forming epitaxial layer 110 on and/or over silicon substrate 101. Gate oxide layers 108 may be formed on and/or over silicon substrate 101 such that they are situated around the sidewalls of gate electrode 106 and may be subsequently removed using an isotropic wet etching method. Specifically, gate oxide layers 108 may not be completely removed so that partial gate oxide layers 108 are formed to a height lower than that of the portions of epitaxial layer 110 formed on and/or over source region 115 and drain region 116. As illustrated in example FIG. 7E, bird's beak 120, gate spacer 114, source region 115 and drain region 116, and protective layer 118 may be formed on and/or over silicon substrate.

Prior to forming protective layer 118, bird's beak 120 may be formed between gate insulation layer 104, gate oxide layer 108, and the portion of epitaxial layer 110 formed on and/or over source region 115 and drain region 116 using a polyoxidation process. Bird's beak 120 may be beneficial to reducing an overlap capacitance between gate electrode 106 and source region 115 and drain region 116 while also having substantially no effect on the thickness of gate insulation layer 104 in the channel region.

Gate spacers 114 may be formed around the sidewalls of gate electrode 106 and gate oxide layer 108. Source region 115 and drain region 116 may be formed in the silicon substrate 101 at positions not corresponding to gate electrode 106.

Protective layer 118 may be formed on and/or over the entire surface of silicon substrate 101. Gate spacers 114 may be formed by depositing a silicon nitride (SiN) layer on and/or over silicon substrate 101 using a CVD process, and patterning the silicon nitride layer using a photolithography process. Gate spacers 114 may be formed around the sidewalls of gate electrode 106 and gate oxide layer 108.

Source region 115 and drain region 116 having an underside junction may be formed by injecting ions into exposed LDD region 112 of silicon substrate 101. A heat-treatment process is then performed to activate the injected ions. An insulation layer such as a SiN layer, may be deposited using a LPCVD method to form protective layer 118. Protective layer 118 may serve as a capping layer for protecting a transistor and an etching-barrier layer.

Example FIGS. 8 and 9 illustrate a simulated view of the semiconductor device in accordance with embodiments illustrated in example FIG. 4 and another semiconductor device. The semiconductor device in accordance with embodiments is configured such that the LDD region has a shallower junction depth from a channel surface than the semiconductor device illustrated to the right. Due to the utilization of an epitaxial layer, the upper surface of the silicon substrate is higher than the substrate illustrated in the semiconductor device illustrated to the right. Consequently, as compared to the semiconductor device to the right, the semiconductor device in accordance with embodiments enables an increased amount of ions to be injected into the LDD region. This is turn, results in the LDD region being capable of achieving a greater thickness, resulting in a lower resistance.

As illustrated in example FIG. 10A, the variation of a threshold voltage (Vtlin), which is measured at a constant current value depending on a channel length (Lmet), of the semiconductor device in accordance with embodiments and another semiconductor device. Example FIG. 10B illustrates the variation of a threshold voltage (Vtext) measured based on transconductance (gₘ) depending on the channel length (Lmet) of the semiconductor devices in accordance with embodiments and the other semiconductor device.

As illustrated in example FIGS. 10A and 10B, considering the threshold voltage (Vtlin) measured at a constant current value depending on the channel length (Lmet) and the threshold voltage (Vtext) measured based on transconductance (gₘ), the semiconductor devices provided in accordance with embodiments can maintain a more uniform threshold voltage even if the channel length is reduced.

As illustrated in example FIG. 11A, the variation of operating voltage-current (Idsat) depending on the leakage current (Ioff) of the semiconductor devices in accordance with embodiments and another semiconductor device. FIG. 11B illustrates the variation of operating voltage-current (Idsat) depending on a drain index barrier lowering (DIBL) of the semiconductor devices in accordance with embodiments and another semiconductor device.

As illustrated in example FIG. 11A, the variation of the operating voltage-current (Idsat) depending on the leakage current (Ioff) of the semiconductor devices provided in accordance with embodiments is substantially equal to that of the other semiconductor device. Consequently, the same operating voltage-current (Idsat) can be achieved under the condition of the same leakage current (Ioff). The semiconductor devices manufactured in accordance with embodiments show substantially minimal deterioration.

Moreover, short channel effects are aggravated in proportion to an aggravated DIBL. Therefore, as illustrated in example FIG. 11B, the semiconductor devices manufactured in accordance with embodiments can achieve an improvement in short channel effects because of the low DIBL exhibited when compared to the other semiconductor device at the same operating voltage-current (Idsat).

As illustrated in example FIG. 12, the semiconductor devices manufactured in accordance with embodiments can minimize an overlap area between the gate electrode and the LDD region under a channel region and an electric field from the LDD region to the channel region to thereby achieve a reduction in hot carrier effects. As illustrated in example FIG. 13, the semiconductor devices manufactured in accordance with embodiments can also reduce an overlap capacitance between the gate electrode and the drain region.

A semiconductor device and method for manufacturing the same in accordance with embodiments are beneficial in that they can reduce an overlap capacitance between a gate electrode and source/drain regions, minimize short channel effects and hot carrier effects. Formation of an LDD region and source/drain regions in accordance with embodiments makes it possible to obtain a shallow junction depth from a channel surface without lowering ion injection energy, and thus, provides stability in the ion injection process. Due to the use of rapid thermal annealing (RTA) heat-treatment rather than a spike annealing process, the stable activation of ions can be obtained. This has the effect of reducing overall manufacturing costs by reducing the requirement for additional equipment to perform additional processes during manufacturing.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
an isolation layer formed over a silicon substrate for dividing the silicon substrate into an active region and an inactive region;
a gate electrode formed over the silicon substrate;
a gate oxide layer formed around a sidewall of the gate electrode to expose an upper portion of a sidewall of the gate electrode;
a gate insulation layer formed between the silicon substrate and the gate electrode;
an epitaxial layer formed over the gate electrode and the active region around the gate electrode, wherein the epitaxial layer has a width larger than the width of the gate electrode and the gate insulation layer;
a lightly doped drain (LDD) region formed in a surface of the silicon substrate around the gate electrode;
a gate spacer formed around the sidewall of the gate electrode and the gate oxide layer;
source and drain regions formed in the surface of the silicon substrate at side areas of the gate spacer; and
a protective layer formed over the entire surface of the silicon substrate and the epitaxial layer.

2. The apparatus of claim 1, wherein the epitaxial layer formed on the gate electrode has a mushroom-like shape.

3. The apparatus of claim 1, wherein the gate oxide layer is etched to a height lower than the height of the portion of the epitaxial layer provided directly over the source and drain regions.

4. The apparatus of claim 3, wherein a bird's beak is formed between the gate insulation layer, the gate oxide layer, and the portion of the epitaxial layer provided directly over the source and drain regions.

5. A method comprising:
forming a gate insulation layer over a silicon substrate having an isolation layer for dividing the silicon substrate into an active region and an inactive region;
forming a gate electrode over the gate insulation layer;
forming a gate oxide layer over the silicon substrate to expose an upper surface and a partial sidewall of the gate electrode;
forming an epitaxial layer over the gate electrode and the active region around the gate electrode to a width larger than the width of the gate insulation layer;
forming an LDD region in a surface of the silicon substrate around the gate electrode;
forming a gate spacer around the sidewall of the gate electrode and the gate oxide layer;
forming source and drain regions by injecting ions into the surface of the silicon substrate adjacent sides of the gate spacer; and
forming a protective layer over the entire surface of the silicon substrate.

6. The method of claim 5, further comprising:
patterning the gate oxide layer using an isotropic wet etching method after forming the epitaxial layer; and
performing a poly-oxidation process prior to forming the protective layer.

7. The method of claim 6, wherein the gate oxide layer is patterned to a height lower than the height of the portion of the epitaxial layer formed around the gate electrode.

8. The method of claim 5, wherein the gate oxide layer and the gate insulation layer are patterned simultaneously using an anisotropic over-etching process.

9. The method of claim 5, wherein the epitaxial layer is formed using a homo epitaxy method.

10. The method of claim 5, wherein the gate oxide layer has a thickness of between approximately 20 Å to 150 Å.

11. A method comprising:
forming an isolation layer over a silicon substrate to divide the silicon substrate into an active region and an inactive region;
forming a gate electrode over the silicon substrate;
forming a gate oxide layer having a thickness of between approximately 20 to 150 Å over the silicon substrate to expose an upper portion of a sidewall of the gate electrode;
forming a gate insulation layer between the silicon substrate and the gate electrode;
forming an epitaxial layer over the gate electrode and the active region to a width larger than the width of the gate electrode and the gate insulation layer;
forming a lightly doped drain region in a surface of the silicon substrate around the gate electrode;
forming a gate spacer around the sidewall of the gate electrode and a sidewall of the gate oxide layer;
forming source and drain regions having an underside junction in the surface of the silicon substrate;
etching the gate oxide layer to a height lower than the height of the portion of the epitaxial layer provided directly over the source and drain regions; and
forming a bird's beak between the gate insulation layer, the gate oxide layer, and the portion of the epitaxial layer provided directly over the source and drain regions; and
forming a protective layer over the entire surface of the silicon substrate.

12. The method of claim 11, wherein the isolation layer is formed over the silicon substrate using a shallow trench isolation (STI) process.

13. The method of claim 11, wherein the gate insulation layer comprises an insulation material.

14. The method of claim 13, wherein said insulation material comprises at least one of SiO₂ and SiON.

15. The method of claim 11, wherein the gate oxide layer is formed by oxidizing the surface of the gate electrode.

16. The method of claim 11, wherein an upper surface and a sidewall portion of the gate electrode are exposed using an anisotropic over-etching process.

17. The method of claim 11, wherein the forming the gate spacers comprises depositing a silicon nitride layer on the silicon substrate using a chemical vapor deposition process and patterning the silicon nitride layer using a photolithography process.

18. The method of claim 11, wherein forming the protective layer comprises depositing an insulation layer using a low pressure chemical vapor deposition process.

19. The method of claim 18, wherein said insulation layer comprises silicon nitride.

20. The method of claim 11, wherein the bird's beak is formed using a spolyoxidation process.
